(19) United States
(12) Patent Application Publication
(10) Pub. No.: US 2026/0363072 A1
(43) Pub. Date: Nov. 12, 2026

(54) THERMAL INTERFACE MATERIAL

(71) Applicant: TCLAD Technology Corporation, TOUFEN CITY (TW)

(72) Inventors: Kai-Wei LO, Zhubei City (TW); YU-HSIEN CHO, Hsinchu City (TW); HSIN-LUNG CHEN, Zhubei City (TW)

(21) Appl. No.: 19/250,943

(22) Filed: Jun. 26, 2025

(30) Foreign Application Priority Data
May 6, 2025 (TW) 114116878

(51) Int. Cl. H10W 40/25; C08K 3/04; H10W 72/30

(52) U.S. Cl. CPC H10W 40/251; C08K 3/04; H10W 40/254; C08K 2201/001; C08K 2201/005; H10W 72/325; H10W 72/353; H10W 72/354

(57) ABSTRACT

A thermal interface material includes a matrix and a thermally conductive filler. The matrix has a fluorine-containing polymer, and the thermally conductive filler has a carbon-containing mineral. The total weight of the matrix and the thermally conductive filler is taken as 100%, and the carbon-containing mineral accounts for 70% to 95%.

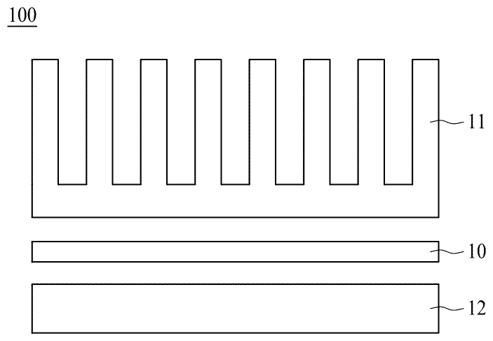

### BACKGROUND OF THE INVENTION

### (1) Field of the Invention

The present application relates to a thermal interface material, and more specifically, to a thermal interface material having excellent thermal conductivity.

### (2) Description of the Related Art

Power electronic devices, light-emitting diode devices, or other semiconductor devices typically generate a significant amount of heat during operation. If the heat cannot dissipate effectively, the performance of these semiconductor devices may be compromised, potentially leading to malfunction or even burnout. These semiconductor devices are usually mounted onto a heat sink, with a thermal interface material placed between them to bond the device to the heat sink. By utilizing the gap-filling (or elastic) properties and good thermal conductivity of the thermal interface material, the interfacial thermal resistance between the semiconductor device and the heat sink is reduced, thereby effectively transferring the heat generated by the semiconductor device to the heat sink for dissipation.

Traditionally, the polymer system used in thermal interface materials may be based on either an organic silicone polymer system or an epoxy resin system. The organic silicone polymer system may include silicone grease or silicone rubber, known for their low viscosity and good flexibility. However, after being used over time, these materials may experience oil migration to unwanted areas and hardening issues. Although the epoxy resin system offers advantages such as good adhesion and low cost, its adhesion is often excessively strong, and it is rigid, which can limit its applicability or result in higher interfacial thermal resistance. In addition, it may undergo material deterioration when exposed to high temperatures for extended periods. To enhance the thermal conductivity of thermal interface materials, thermally conductive fillers are often added. Metal oxides (e.g., aluminum oxide or zinc oxide), metal nitrides (e.g., boron nitride or aluminum nitride) and/or similar materials are commonly used as thermally conductive fillers. However, the thermal conductivity of metal oxide/nitride powders is significantly lower than that of metal powders, and they tend to exhibit high oil absorption during the manufacturing process. As a result, their loading capacity is limited, which in turn restricts the thermal conductivity performance of the composite material.

### SUMMARY OF THE INVENTION

In accordance with an aspect of the present invention, a thermal interface material includes a matrix and a thermally conductive filler. The matrix has a fluorine-containing polymer. The thermally conductive filler has a carbon-containing mineral. The total weight of the matrix and the thermally conductive filler is taken as 100%, and the carbon-containing mineral accounts for 70% to 95%.

In an embodiment, the carbon-containing mineral is diamond.

In an embodiment, the fluorine-containing polymer is selected from the group consisting of fluorine rubber, perfluorinated rubber, tetrafluoroethylene propylene rubber, and fluoroalkoxyphosphazene rubber.

In an embodiment, the fluorine-containing polymer is fluorine rubber.

In an embodiment, the total weight of the matrix and the thermally conductive filler is taken as 100%, with the matrix accounting for 5% to 20% and the carbon-containing mineral accounting for 80% to 95%.

In an embodiment, the thermal interface material satisfies a relation during X-ray irradiation: I~q^{a}, wherein: an equivalence relation exists between I and q; I stands for scattering intensity; and q stands for scattering vector, wherein q ranges from 0.007 Å⁻¹ to 0.1 Å⁻¹, and a ranges from −3.3 to −3.9.

In an embodiment, the thermal interface material has a thermal conductivity ranging from 10 W/mK to 50 W/mK.

In an embodiment, the thermal interface material is formed by extrusion, calendering or injection molding.

In an embodiment, the matrix does not include epoxy resin and silicone rubber.

In an embodiment, the thermally conductive filler does not include a metal compound filler, wherein the metal compound filler is selected from the group consisting of zirconium nitride, aluminum nitride, aluminum oxide, magnesium oxide, zinc oxide, titanium dioxide, and combinations thereof.

In an embodiment, the thermally conductive filler does not include a metal filler.

In an embodiment, the thermally conductive filler has an average particle size ranging from 0.5 μm to 80 μm.

### BRIEF DESCRIPTION OF THE DRAWINGS

The present application will be described according to the appended drawings in which:

The sole FIGURE shows a cross-sectional view of an electronic apparatus having a thermal interface material in accordance with the present invention.

### DETAILED DESCRIPTION OF THE INVENTION

The making and using of the presently preferred illustrative embodiments are discussed in detail below. It should be appreciated, however, that the present application provides many applicable inventive concepts that can be embodied in a wide variety of specific contexts. The specific illustrative embodiments discussed are merely illustrative of specific ways to make and use the invention, and do not limit the scope of the invention.

Please refer to the sole FIGURE, which shows a cross-sectional view of an electronic apparatus 100 having a thermal interface material 10. The thermal interface material 10 can be adhered to the surface of a heat sink, and then placed on a heat-generating device. The details are described as follows. The electronic apparatus 100 includes a heat sink 11, an electronic device 12, and the thermal interface material 10 as previously mentioned. The heat sink 11 has a front side and a back side opposite to the front side. The heat sink 11 may be a fin-type heat sink, with a plurality of fin structures extending from its front side, while its back side remains substantially smooth. The electronic device 12 has a front side and a back side opposite to the front side. The back side of the electronic device 12 faces the back side of the heat sink 11. It is understood that the surface of the back side of the heat sink 11 is actually uneven when viewed at a microscopic scale, as is the back side of the electronic device 12. If the back side of the heat sink 11 is directly attached to the back side of the electronic device 12, numerous gaps form at their interface, leading to the issue of high thermal contact resistance. However, the aforementioned gaps can be filled with the thermal interface material 10, thereby reducing the thermal contact resistance at the interface. Accordingly, the thermal interface material 10 is disposed between the heat sink 11 and the electronic device 12, attaching to the back side of the heat sink 11 and the back side of the electronic device 12. The heat generated by the electronic device 12 can thus be effectively conducted through the thermal interface material 10.

The present invention aims to modify the thermal interface material 10 as previously mentioned. The thermal interface material 10 includes a matrix and a thermally conductive filler. The matrix has a fluorine-containing polymer, and the thermally conductive filler has a carbon-containing mineral. The total weight of the matrix and the thermally conductive filler is taken as 100%, and the carbon-containing mineral accounts for 70% to 95%. Thermally conductive fillers can be categorized into metal fillers and non-metal fillers. Silver is a commonly used metal filler in the industry; although it offers excellent thermal conductivity, it poses a risk of current leakage during operation. Metal nitrides, such as aluminum nitride, are commonly used non-metal fillers in the industry; however, their powders exhibit high oil absorption. The present invention finds that the addition of a specified amount of a mineral (e.g., diamond), in combination with the fluorine-containing polymer, results in a composite material that not only exhibits excellent thermal conductivity (20 W/mK to 50 W/mK) but also demonstrates outstanding performance in other physical properties. Preferably, the thermally conductive filler, which contains the aforementioned carbon-containing mineral, has an average particle size ranging from 0.5 μm to 80 μm.

The fluorine-containing polymer may be selected from the group consisting of fluorine rubber (FKM), perfluorinated rubber (FFKM), tetrafluoroethylene propylene rubber (FEPM), and fluoroalkoxyphosphazene rubber (FZ). Preferably, the fluorine-containing polymer is fluorine rubber. Fluorine rubber may be selected from commercial products such as DAI-EL™ G751, G752, G755, G763, G781, G783, G558, G575, G902 (Daikin Industries, Ltd.); or 3M™ Dyneon™ FC2211, FC2210, FC2145, FE5522, FE5832, FT2350.

The present invention further finds that the thermal interface material 10 can achieve the aforementioned excellent thermal conductivity as long as the composition of the thermal interface material 10 satisfies a specific relation between X-ray scattering intensity and X-ray scattering vector. More specifically, the thermal interface material 10 satisfies a relation of I~q^{a} during X-ray irradiation. There is an equivalence relation between I and q. I stands for scattering intensity. q stands for scattering vector. q ranges from 0.007 A⁻¹ to 0.1 Å⁻¹, and a ranges from −3.3 to −3.9.

According to Porod's law, if a surface is smooth, the scattering intensity of X-rays satisfies the relation of I_{(q)}~Sq⁻⁴, where I represents the scattering intensity, S is the surface area of particles, and q is the scattering vector. In addition, q⁻⁴ corresponds to the factor 1/sin⁴ θ in the Fresnel equations of reflection. With the advent of fractal mathematics, the classical relation from Porod's law can be generalized to I~q^{a}, as used in the present invention. The present invention finds that a composite material exhibits better performance in thermal conductivity if q and the exponent of q are restricted to specific ranges. More specifically, vector (q) to be analyzed through SAXS (small-angle X-ray scattering) analyzer is below 0.1 Å⁻¹. After analyzing a tested sample (i.e., the thermal interface material 10), a resulting curve of scattering vector (below 0.1 Å⁻¹) versus scattering intensity can be plotted. Subsequently, a fitted straight line corresponding to the resulting curve is obtained through curve fitting, and the slope of the fitted straight line represents the aforementioned a. As described above, when the value of a falls within the range of −3.3 to −3.9, the thermal interface material 10 exhibits excellent thermal conductivity.

In addition, the present invention does not use either epoxy resin or silicone rubber as the matrix of the thermal interface material 10 due to their tendency to degrade and exhibit oil migration. Also, the present invention does not include other metal compound fillers, such as zirconium nitride, aluminum oxide, magnesium oxide, zinc oxide, and/or titanium dioxide.

In order to provide a more specific description of the technical content of the present invention, please refer to the following verification.

TABLE 1

| | | | Proportion of | |
|---|---|---|---|---|
| | | Thermally | matrix | Proportion of |
| Group | Matrix | conductive filler | (wt %) | filler (wt %) |
| C1 | Epoxy | Silver | 25 | 75 |
| | resin | | | |
| C2 | Epoxy | Aluminum | 30 | 70 |
| | resin | nitride | | |
| C3 | Silicone | Aluminum | 10 | 90 |
| | rubber | nitride | | |
| C4 | — | — | — | — |
| E1 | Fluorine | Silver | 20 | 80 |
| | rubber | | | |
| E2 | Fluorine | Diamond and | 20 | 80 |
| | rubber | Silver | | |
| E3 | Fluorine | Diamond | 30 | 70 |
| | rubber | | | |
| E4 | Fluorine | Diamond | 20 | 80 |
| | rubber | | | |
| E5 | Fluorine | Diamond | 5 | 95 |
| | rubber | | | |

TABLE 2

| | | | | Capacity to |
|---|---|---|---|---|
| | | Thermal | | endure bending |
| | | conductivity | | without |
| Group | a | (W/mK) | Shore A hardness | breaking |
| C1 | −3.25 | 15.0 | 99 | X |
| C2 | −3.20 | 10.0 | 99 | X |
| C3 | −3.30 | 20.0 | 44 | X |
| C4 | — | 86.0 | 80 | X |
| E1 | −3.31 | 20.0 | 68 | ⊚ |
| E2 | −3.47 | 25.0 | 65 | ⊚ |
| E3 | −3.34 | 20.0 | 64 | ⊚ |
| E4 | −3.65 | 30.0 | 79 | ◯ |
| E5 | −3.82 | 50.0 | 95 | Δ |

TABLE 3

| | | | | Capacity | | |
|---|---|---|---|---|---|---|
| | | | | to | | |
| | | | | endure | | |
| | Thermally | | | bending | | |
| | conductive | Thermal | Mechanical | without | Compressibility | |
| Matrix | filler | conductivity | strength | breaking | (Elasticity) | Reworkability |
| Epoxy | Aluminum | X | ⊚ | X | X | X |
| resin | nitride | | | | | |
| Silicone | Aluminum | Δ | X | Δ | ⊚ | ◯ |
| rubber | nitride | | | | | |
| Fluorine | Aluminum | Δ | ◯ | ⊚ | ◯ | ⊚ |
| rubber | nitride | | | | | |
| Silicone | Diamond | ⊚ | X | Δ | ⊚ | ◯ |
| rubber | | | | | | |
| Fluorine | Diamond | ⊚ | ⊚ | ⊚ | ⊚ | ⊚ |
| rubber | | | | | | |

Please refer to Table 1, which shows the composition of the thermal interface material for each group. Groups C1 to C4 correspond to comparative examples C1 to C4, while groups E1 to E5 correspond to embodiments E1 to E5 of the present invention. In the comparative examples C1 to C3, the matrix is either epoxy resin or silicone rubber, and the thermally conductive filler is either silver or aluminum nitride. In the embodiments E1 to E5 of the present invention, the matrix is fluorine rubber, and the thermally conductive filler is either silver or diamond. In addition, a conventionally used thermally conductive plate is also tested, corresponding to the comparative example C4, in which the thermally conductive plate is made of indium foil.

During manufacturing, the matrix and the thermally conductive filler are blended in a kneader to form a kneaded paste, which is then subjected to extrusion, calendering or injection molding to produce sheets of a desired thickness. No solvent is required throughout the entire process. Due to the use of solventless extrusion, calendering or injection molding, high-viscosity materials are unsuitable for the present application. In contrast, high-viscosity materials can be used in solvent-based processes, such as daubing or screen printing. Compared to traditional solvent-based processes, the present invention eliminates the need for a solvent-removal step. As a result, there are no solvent residues or voids that may otherwise result from rapid solvent removal.

Please refer to Table 2. The parameter “a” refers to the exponent of q in the equivalence relation of I~q^{a}. After analysis using a SAXS analyzer, the resulting curve of scattering vector q versus scattering intensity I can be plotted, and the value of a can be calculated accordingly. During SAXS analysis, the exposure time is 0.5 seconds; the exposure period is 0.501 seconds; the wavelength is 0.8259 Å; the beam energy is 1.501×10⁴ eV; and the distance between the tested sample and the analyzer is 3.09 meters. Based on the generalized relation I~q^{a} from Porod's law, the value of a can be controlled within a specified range. It can be observed that the value of a varies from −3.31 to −3.82, depending on the composition shown in Table 1. As the slope increases (i.e., the value of a decreases), the thermal conductivity accordingly. In particular, fluorine rubber is highly compatible with diamond (see embodiments E3 to E5), and this combination yields the highest thermal conductivity. In Table 2, the combinations of the matrix and the thermally conductive filler in the present invention demonstrate better thermal conductivity performance than the conventional comparative examples C1 to C3. Although the comparative example C4 exhibit excellent thermal conductivity, it uses a metal plate (i.e., indium foil as previously mentioned) for thermal conduction. However, the metal plate is prone to cracking or breaking during installation. In addition, in terms of the capacity to endure bending without breaking, the comparative examples C1 to C3 show poorer results. Generally, the thermal interface materials of the comparative examples C1 to C3 are relatively rigid, resulting in poor flowability to fill the gaps at the interface between the heat sink 11 and the electronic device 12 as previously mentioned. In Table 2 and Table 3, for ease of reading, “X” indicates poor; “Δ” indicates fair; “∘” indicates good; “⊚” indicates excellent.

Please refer to Table 3, which shows different combinations of the matrix and the thermally conductive filler. When the combination consists of epoxy resin and aluminum nitride, only the mechanical strength is rated as excellent. When the combination consists of silicone rubber and aluminum nitride, although the elasticity is rated as excellent, the mechanical strength is poor. When the combination consists of fluorine rubber and aluminum nitride, the overall performance is generally good. When the combination consists of silicone rubber and diamond, only the mechanical strength is rated as poor, while the other properties are generally good. When the combination consists of fluorine rubber and diamond, the performance is rated as excellent in all aspects, including thermal conductivity, mechanical strength, capacity to endure bending without breaking, compressibility (elasticity), and reworkability. These results indicate that fluorine rubber is highly compatible with diamond, enabling the thermal interface material not only to perform well in thermal conductivity but also to significantly improve other physical properties.

The above-described embodiments of the present invention are intended to be illustrative only. Numerous alternative embodiments may be devised by persons skilled in the art without departing from the scope of the following claims.

What is claimed is:

1. A thermal interface material, comprising:
a matrix having a fluorine-containing polymer; and
a thermally conductive filler having a carbon-containing mineral, wherein the total weight of the matrix and the thermally conductive filler is taken as 100%, and the carbon-containing mineral accounts for 70% to 95%.

2. The thermal interface material of claim 1, wherein the carbon-containing mineral is diamond.

3. The thermal interface material of claim 1, wherein the fluorine-containing polymer is selected from the group consisting of fluorine rubber, perfluorinated rubber, tetrafluoroethylene propylene rubber, and fluoroalkoxyphosphazene rubber.

4. The thermal interface material of claim 3, wherein the fluorine-containing polymer is fluorine rubber.

5. The thermal interface material of claim 1, wherein the total weight of the matrix and the thermally conductive filler is taken as 100%, with the matrix accounting for 5% to 20% and the carbon-containing mineral accounting for 80% to 95%.

6. The thermal interface material of claim 1, wherein the thermal interface material satisfies a relation during X-ray irradiation:
I~q^{a}, wherein:
an equivalence relation exists between I and q;
I stands for scattering intensity; and
q stands for scattering vector, wherein q ranges from 0.007 Å⁻¹ to 0.1 Å⁻¹, and a ranges from −3.3 to −3.9.

7. The thermal interface material of claim 1, wherein the thermal interface material has a thermal conductivity ranging from 10 W/mK to 50 W/mK.

8. The thermal interface material of claim 1, wherein the thermal interface material is formed by extrusion, calendering or injection molding.

9. The thermal interface material of claim 1, wherein the matrix does not comprise epoxy resin and silicone rubber.

10. The thermal interface material of claim 1, wherein the thermally conductive filler does not comprise a metal compound filler, wherein the metal compound filler is selected from the group consisting of zirconium nitride, aluminum nitride, aluminum oxide, magnesium oxide, zinc oxide, titanium dioxide, and combinations thereof.

11. The thermal interface material of claim 1, wherein the thermally conductive filler does not comprise a metal filler.

12. The thermal interface material of claim 1, wherein the thermally conductive filler has an average particle size ranging from 0.5 μm to 80 μm.
